(19) United States
(12) Patent Application Publication
(10) Pub. No.: US 2011/0174611 A1
(43) Pub. Date: Jul. 21, 2011

(54) SUPPORT DEVICE AND COATING DEVICE USING SAME

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 12/853,503

(22) Filed: Aug. 10, 2010

(30) Foreign Application Priority Data
Jan. 21, 2010 (TW) 99101573

(51) Int. Cl. C23C 14/50; C23C 14/34

(52) U.S. Cl. 204/298.15

(57) ABSTRACT

An exemplary coating device includes a target material and a support device configured for supporting a workpiece. The support device includes a support frame and a holding member. The support frame includes a support member and a support arm disposed on the support member. One end of the holding member is configured for attaching the workpiece thereon, and an opposite end of the holding member is adjustably engaged with the support arm so that the workpiece is a desired distance from the target material.

### BACKGROUND

1. Technical Field

The present disclosure relates to coating devices used in manufacturing, and particularly, to a coating device with a support device.

2. Description of Related Art

In a surface treating process, such as sputtering, workpieces are hung up in a treating chamber by various hooks. However, the hooks tend to clutter and are somewhat inconvenient to use. In addition, with many systems that use hooks, it is difficult to adjust the distance between the workpieces and a target material. As a result, different hooks must be provided for hanging different workpieces. This is inconvenient and costly.

Therefore, it is desirable to provide a support device and a coating device utilizing the support device which can overcome the limitations described above.

### BRIEF DESCRIPTION OF THE DRAWINGS

FIG. 1 is a schematic cross-sectional view of a coating device, according to an exemplary embodiment.

FIG. 2 is an enlarged, exploded, isometric view of a support device of the coating device of FIG. 1.

FIG. 3 is an enlarged, exploded, isometric view of a support device of a coating device according to another exemplary embodiment.

### DETAILED DESCRIPTION

Embodiments of the disclosure will now be described in detail, with reference to the accompanying drawings.

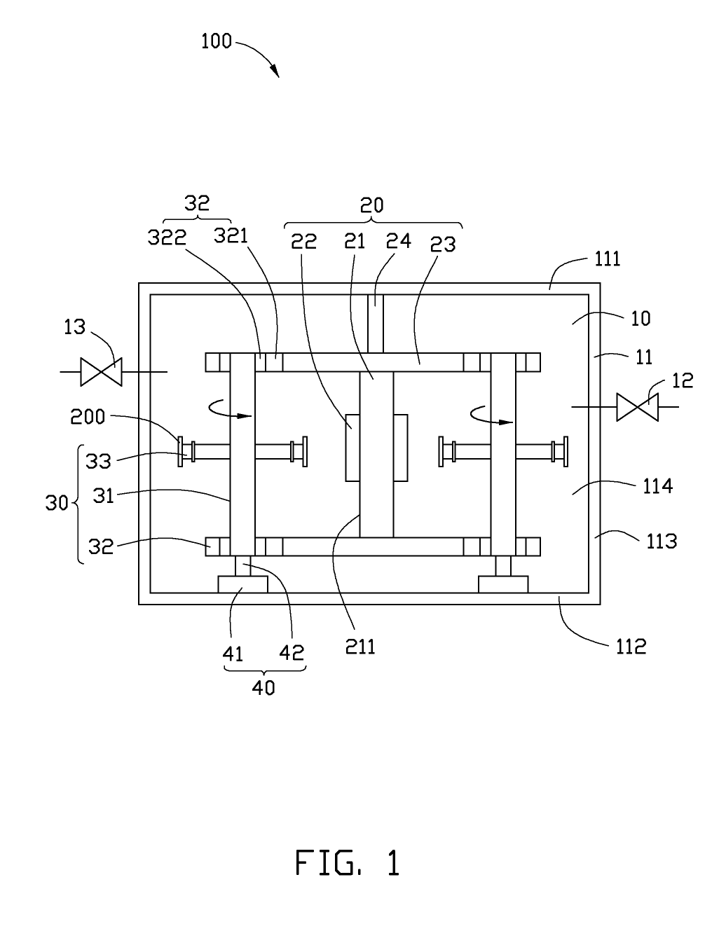

Referring to FIG. 1, a coating device 100, according to an exemplary embodiment, is provided to coat workpieces 200. The coating device 100 comprises a vacuum chamber 10, a sputtering device 20, a number of support devices 30, and a number of actuators 40. The sputtering device 20 and the support devices 30 are received in the vacuum chamber 10. The actuators 40 rotate the support devices 30 as needed.

The vacuum chamber 10 is generally cylindrical, and includes a shell 11, a gas inlet system 12, and a gas outlet system 13. The shell 11 includes an upper plate 111, a lower plate 112, and a peripheral sidewall 113. The peripheral sidewall 113 connects the upper plate 111 to the lower plate 112, whereby a receiving space 114 is formed. The gas inlet system 12 can communicate the receiving space 114 to a gas source (not shown) for filling the receiving space 114 with noble gas. The gas outlet system 13 communicates the receiving space 114 to a waste gas collection device (not shown), so that waste and excess gas is vented from the receiving space 114.

The sputtering device 20 includes a first support member 21, a target material 22, two shielding plates 23, and a connecting member 24. The first support member 21 is a cylinder, and includes a circumferential surface 211. The target material 22 is attached on the circumferential surface 211. The two shielding plates 23 are in the shape of circular plates (disks), and are respectively disposed on two ends of the first support member 21. The connecting member 24 is located between the upper plate 111 of the vacuum chamber 10 and an upper one of the shielding plates 23.

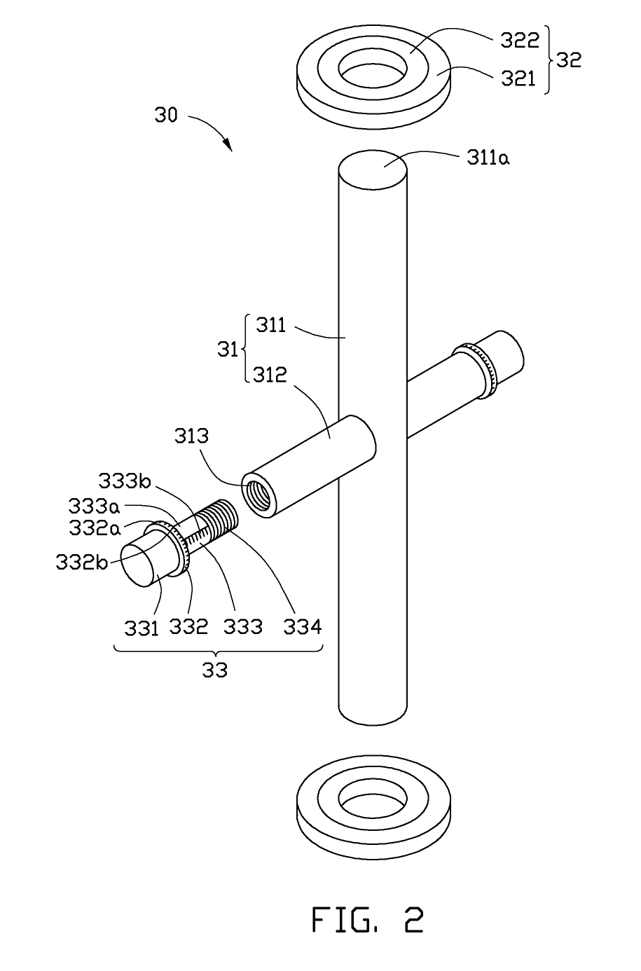

Further referring to FIG. 2, each support device 30 includes a support frame 31, two bearings 32, and at least one holding member 33. In the illustrated embodiment, there are two holding members 33. The support frame 31 includes a second support member 311 and two support arms 312. The second support member 311 is a cylinder having a cylindrical side surface 311a. Each support arm 312 is cylindrical. The support arms 312 are perpendicularly disposed on the cylindrical side surface 311a, and are symmetrically opposite each other. That is, the support arms 312 are positioned at a same level. One end of each support arm 312, far away from the second support member 311, defines a screw hole 313 therein along a central axis thereof. Each bearing 32 includes an outer ring 321 and an inner ring 322 rotatably received in the outer ring 321. The outer rings 321 of the bearings 32 are interferentially fixed in corresponding edge portions of two corresponding shielding plates 23. The two bearings 32 of one support device 30 are coaxial with each other. The inner rings 322 of the bearings 32 are sleeved over opposite ends of the second support member 311, with the ends of the second support member 311 interferentially fitted in the inner rings 322.

Each of the holding members 33 is a cylinder, and includes a magnetic portion 331, an adjusting portion 332, a scale portion 333, and a screw portion 334. The magnetic portion 331 is made of magnetic material. The adjusting portion 332 connects the magnetic portion 331 to the scale portion 333. The outer diameter of the adjusting portion 332 is larger than that of the magnetic portion 331, and larger than that of the scale portion 333. The adjusting portion 332 includes a first outer surface 332a. A first scale 332b is provided around the first outer surface 332a. In the illustrated embodiment, the first scale 332b comprises a series of notches (hereinafter, “marks”) defined in the first outer surface 332a. The scale portion 333 includes a second outer surface 333a. A second scale 333b is provided on the second outer surface 333a, parallel to a central axis of the scale portion 333. In the illustrated embodiment, the second scale 333b comprises a series of notches (hereinafter, “marks”) defined in the second outer surface 333a. The pitch between two adjacent marks of the first scale 332b is equal to the pitch between two adjacent marks of the second scale 333b. The screw portion 334 is disposed at an end of the scale portion 333 farthest away from the adjusting portion 332. The scale portion 333 and the screw portion 334 have substantially the same outer diameter.

Each actuator 40 comprises a stator 41, and a rotor 42 extending outward from the center of the stator 41. The stator 41 is mounted on the lower plate 112 of the vacuum chamber 10. The rotor 42 is connected to the corresponding second support member 311 to rotate the corresponding holding members 33.

In assembly, the screw portion 334 of each holding member 33 is partially threadedly engaged in the screw hole 313 of the corresponding support arm 312. After the support arm 312 has been positioned opposite to the target material 22, the distance between the magnetic portion 331 and the target material 22 can be adjusted according to the thickness of the film to be coated on the workpieces 200. Then a workpiece 200 is attached on the magnetic portion 331, with the coating surface of the workpiece 200 facing away from the magnetic portion 331.

It should be noted that a negative voltage is applied to the workpiece 200 and a positive voltage is applied to the target material 22. Therefore, a great voltage difference (drop) between the target material 22 and the workpiece 200 can be generated.

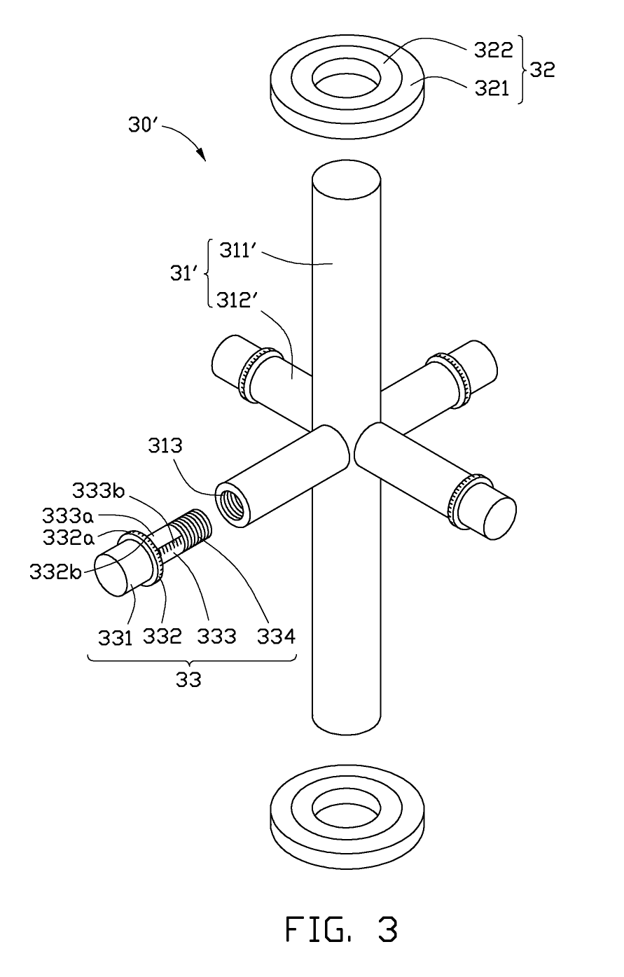

Referring to FIG. 3, a support device 30′ according to another exemplary embodiment is shown. The support device 30′ includes a support frame 31′, which includes a second support member 311′ and four support arms 312′. The four support arms 312′ perpendicularly extend from the middle of the second support member 311′. The support arms 312′ are at a same level, and are equally angularly spaced apart from each other (i.e. radially symmetrical), thereby forming a cruciform structure for holding four workpieces 200 thereat. It should be noted that the number of the support arms 312′ may be varied as required. To reduce or increase the number of the support arms 312′ for holding fewer or more workpieces 200, and to modify the shape of the support frame 31′ correspondingly, should be considered as falling within the scope and the spirit of the present disclosure.

In operation of the coating device 100, the actuators 40 rotate the support devices 30. The vacuum chamber 10 is evacuated via the gas outlet system 13 until the air pressure in the vacuum chamber 10 is measured at about 1.3×10⁻³ Pa (pascals). Then a first noble gas and a second noble gas are filled in the vacuum chamber 10 via the gas inlet system 12. A glow discharge is generated by the application of the voltage difference through the first noble gas at low pressure in the vacuum chamber 10, whereby a multiplicity of electrons are generated. The second noble gas is excited by the electrons and generates plasma. The target material 22 is bombarded by the plasma under force of the voltage difference applied, and generates a multiplicity of target material atoms. The target material atoms are coated on the workpieces 200.

It will be understood that the particular embodiments and methods are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A coating device for coating a workpiece, the coating device comprising:
a vacuum chamber;
a sputtering device received in the vacuum chamber and comprising a first support member and a target material attached on the first support member; and
a support device received in the vacuum chamber and comprising a support frame and a holding member; the support frame comprising a second support member and a support arm disposed on the second support member; one end of the holding member configured for holding the workpiece thereon, and an opposite end of the holding member adjustably engaged with the support arm so that the workpiece is a desired distance from the target material.

2. The coating device in claim 1, further comprising an actuator connected to the second support member to rotate the support frame.

3. The coating device in claim 1, wherein the vacuum chamber comprises a shell, and the shell comprises an upper plate, a lower plate, and a peripheral sidewall between the upper plate and the lower plate, the upper plate, the lower plate, and the peripheral sidewall cooperatively forming a receiving space receiving the sputtering device and the support device therein.

4. The coating device in claim 3, wherein the sputtering device further comprises two shielding plates respectively disposed on two ends of the first support member, and a connecting member that interconnects the upper plate of the shell and an upper one of the shielding plates.

5. The coating device in claim 4, wherein one end of the support arm far away from the support member defines a screw hole therein along a center axis thereof.

6. The coating device in claim 5, wherein the holding member is a cylinder, and comprises a magnetic portion made of magnetic material and a screw portion, the screw portion at least partially threadedly engaged in the screw hole.

7. The coating device in claim 6, wherein the holding member further comprises an adjusting portion and a scale portion, the adjusting portion and the scale portion are between the magnetic portion and the screw portion, with the adjusting portion adjacent the magnetic portion and the scale portion adjacent the screw portion; the adjusting portion comprises a first outer surface, and a first scale is defined around the circumference of the first outer surface; and the scale portion comprises a second outer surface, and a second scale is defined on the second outer surface parallel to a central axis of the scale portion.

8. The coating device in claim 7, wherein a pitch between two adjacent marks of the first scale equals a pitch between two adjacent marks of the second scale.

9. The coating device in claim 7, wherein the support device further comprises two bearings, each bearing comprises an outer ring and an inner ring rotatably received in the outer ring; the outer ring of each bearing is interferentially fixed in a corresponding edge portion of a corresponding shielding plate; and the inner ring of each bearing is sleeved over one of opposite ends of the second support member, with the ends of the second support member interferentially fitted in the inner rings.

10. The coating device in claim 1, wherein the support arm is perpendicularly disposed on the second support member.

11. The coating device in claim 1, comprising at least two of the support arms and at least two of the holding members, wherein the support arms are located at a same level on the second support member, and are equally angularly spaced from each other.

12. A support device for supporting a workpiece, the support device comprising:
a support frame comprising a support member and a support arm disposed on the support member; and
a holding member adjustably engaged with one end of the support arm, and configured for attaching the workpiece thereon.

13. The support device in claim 12, wherein one end of the support arm far away from the support member defines a screw hole therein along a center axis thereof.

14. The support device in claim 12, wherein the holding member is a cylinder, and comprises a magnetic portion made of magnetic material and a screw portion, the screw portion at least partially threadedly engaged in the screw hole.

15. The support device in claim 14, wherein the holding member further comprises an adjusting portion and a scale portion, the adjusting portion and the scale portion are between the magnetic portion and the screw portion, with the adjusting portion adjacent the magnetic portion and the scale portion adjacent the screw portion; the adjusting portion comprises a first outer surface, and a first scale is defined around the circumference of the first outer surface; and the scale portion comprises a second outer surface, and a second scale is defined on the second outer surface parallel to a central axis of the scale portion.

16. The support device in claim 15, wherein a pitch between two adjacent marks of the first scale equals a pitch between two adjacent marks of the second scale.

17. The support device in claim 12, wherein the support arm is perpendicularly disposed on the support member.

18. The support device in claim 12, comprising at least two of the support arms and at least two of the holding members, wherein the support arms are located at a same level on the support member, and are equally angularly spaced from each other.

19. A coating device for coating a plurality of workpieces, the coating device comprising:
a vacuum chamber;
a first support member received in the center of the vacuum chamber;
a target material attached on the first support member;
a supporting frame comprising a second support member and a plurality of support arms disposed on the second support member;
a plurality of holding members, one end of each holding member configured for holding one of the workpieces thereon, and an opposite end of each holding member adjustably engaged with one of the support arms so that the workpiece is a desired distance from the target material; and
an actuator arranged for driving the supporting frame to rotate.
